(19) United States
(12) Patent Application Publication
(10) Pub. No.: US 2026/0305221 A1
(43) Pub. Date: Oct. 1, 2026

(54) SEALING METHOD, ELECTRONIC DEVICE, STORAGE MEDIUM, AND SEMICONDUCTOR PROCESSING APPARATUS

(71) Applicant: ACM RESEARCH (SHANGHAI), INC., Shanghai (CN)

(72) Inventors: Geng Hu, Shanghai (CN); Yang Liu, Shanghai (CN); Haibo Hu, Shanghai (CN); Xiaoyan Zhang, Shanghai (CN)

(73) Assignee: ACM RESEARCH (SHANGHAI), INC., Shanghai (CN)

(21) Appl. No.: 19/490,835

(22) PCT Filed: Apr. 22, 2024
(86) PCT No.: PCT/CN2024/089054

§ 371 Date: Dec. 5, 2025

(30) Foreign Application Priority Data
Jun. 7, 2023 (CN) 202310672009.6

(51) Int. Cl. H10P 72/00

(52) U.S. Cl. CPC H10P 72/0402

(57) ABSTRACT

The present application relates to a sealing method, an electronic device, a storage medium, and a semiconductor processing apparatus. Wherein, the semiconductor processing apparatus comprises a splash shield, a splash shield base, a lift module, a detection module, and a control module, and the control module is coupled between the lift module and the detection module, wherein the lift module is configured to drive the splash shield to move up and down; the detection module is configured to detect a gas-flow parameter between the splash shield and the splash shield base; the control module is configured to control the lift module to drive the splash shield to move up and down according to the gas-flow parameter, so as to provide sealing between the splash shield and the splash shield base. Through the present application, the problem in the related art that the wafer yield is reduced due to the poor sealing performance between the splash shield and the splash shield base is solved. The sealing performance between the splash shield and the splash shield base is improved, and thus the wafer yield is also improved.

### FIELD OF THE INVENTION

The present application relates to the field of semiconductor equipment, and in particular to a sealing method, an electronic device, a storage medium, and a semiconductor processing apparatus.

### BACKGROUND

In the wafer manufacturing process, the cleaning process accounts for 20% to 30% of the entire process flow, and as the integration level of integrated circuits increases, the proportion of the cleaning process will also increase. Among wet processes, the single-wafer wet process has been widely applied in recent years due to the good uniformity, repeatability, and stability of the single-wafer wet process. The current single-wafer wet process involves fixing a wafer to be cleaned or etched on a wafer chuck, driving the chuck to rotate, and performing processing on the wafer surface by spraying a chemical solution.

During the wet etching process or the wet cleaning process, different chemical solutions are used according to the particles to be cleaned. While these chemical solutions are used to treat the wafer surface, mist is generated within a chamber. If the mist is not promptly discharged, crystals will be formed within the chamber, or the mist will adhere to the wafer surface and form particles, thereby reducing the yield. Therefore, in the single-wafer wet process, controlling the gas flow rate and direction within a chamber plays a crucial role in particle control.

During processing performed by the current semiconductor processing apparatus, as shown in FIG. 1, after a splash shield 10 is lifted, a hard stop 13 is added between a connecting block 16 of a lift module 14 and a base plate 15 to limit the lifting height of the splash shield 10 along with the lift module 14, and a seal ring 12 is added between the splash shield 10 and a splash shield base 11 for sealing. However, during the research and development process, it was found that due to the fixed thickness of the hard stop 13, after the lift module 14 drives the splash shield 10 to move up, the height of the splash shield 10 becomes fixed once the hard stop 13 abuts against the base plate 15. At this time, there will still be a gap between the splash shield base 11 and the splash shield 10. As a result, during processing, part of the exhaust flow escapes through the gap, leading to a low process exhaust flow rate. This makes the acid vapor on the wafer surface fail to be promptly discharged, and the acid vapor adheres to the edge of the wafer and forms edge particle defects.

At present, no effective solution has been proposed to address the problem in the related art that the wafer yield is reduced due to the poor sealing performance between the splash shield and the splash shield base.

### SUMMARY

An embodiment of the present application provides a sealing method, an electronic device, a storage medium, and a semiconductor processing apparatus to at least solve the problem in the related art that the wafer yield is reduced due to the poor sealing performance between the splash shield and the splash shield base.

In a first aspect, an embodiment of the present application provides a semiconductor processing apparatus comprising a splash shield, a splash shield base, a lift module, a detection module, and a control module, and the control module is coupled between the lift module and the detection module, wherein,
the lift module is configured to drive the splash shield to move up and down;
the detection module is configured to detect a gas-flow parameter between the splash shield and the splash shield base;
the control module is configured to control the lift module to drive the splash shield to move up and down according to the gas-flow parameter, so as to provide sealing between the splash shield and the splash shield base.

In some embodiments, the gas-flow parameter includes gas-flow velocity, and the detection module comprises a velocity sensing unit. The velocity sensing unit is coupled with the control module and is configured to detect the gas-flow velocity between the splash shield and the splash shield base.

In some embodiments, the control module comprises a first determination unit and a first control unit. The first determination unit is coupled with the velocity sensing unit, and the first control unit is coupled between the first determination unit and the lift module, wherein,
the first determination unit is configured to determine whether the gas-flow velocity is greater than a preset gas-flow velocity;
the first control unit is configured to control the lift module to drive the splash shield to move up when the first determination unit determines that the gas-flow velocity is greater than the preset gas-flow velocity, and to control the lift module to halt the upward movement when the gas-flow velocity is smaller than the preset gas-flow velocity, so as to provide sealing between the splash shield and the splash shield base.

In some embodiments, the gas-flow parameter includes spacing, and the detection module comprises a distance measuring unit. The distance measuring unit is coupled with the control module and is configured to measure the spacing between the splash shield and the splash shield base.

In some embodiments, the control module comprises a second determination unit and a second control unit. The second determination unit is coupled with the distance measuring unit, and the second control unit is coupled between the second determination unit and the lift module, wherein,
the second determination unit is configured to determine whether the spacing is greater than a preset spacing;
the second control unit is used to control the lift module to drive the splash shield to move up when the second determination unit determines that the spacing is greater than the preset spacing, and to control the lift module to halt the upward movement when the spacing is smaller than the preset spacing, so as to provide sealing between the splash shield and the splash shield base.

In a second aspect, an embodiment of the present application further provides a sealing method applied to a semiconductor processing apparatus. The semiconductor processing apparatus comprises a splash shield, a splash shield base, and a lift module. The method includes:
detecting a gas-flow parameter between the splash shield and the splash shield base;
controlling the lift module to drive the splash shield to move up and down according to the gas-flow parameter, so as to provide sealing between the splash shield and the splash shield base.

In some embodiments, the gas-flow parameter comprises gas-flow velocity, and detecting the gas-flow parameter between the splash shield and the splash shield base involves:
detecting the gas-flow velocity between the splash shield and the splash shield base.

In some embodiments, after detecting the gas-flow velocity between the splash shield and the splash shield base, the method further includes:
determining whether the gas-flow velocity is greater than a preset gas-flow velocity;
when the gas-flow velocity is determined to be greater than the preset gas-flow velocity, controlling the lift module to drive the splash shield to move up, so as to provide sealing between the splash shield and the splash shield base.

In some embodiments, the gas-flow parameter comprises spacing, and detecting the gas-flow parameter between the splash shield and the splash shield base involves:
measuring the spacing between the splash shield and the splash shield base.

In some embodiments, after measuring the spacing between the splash shield and the splash shield base, the method further includes:
determining whether the spacing is greater than a preset spacing;
when the spacing is determined to be greater than the preset spacing, controlling the lift module to drive the splash shield to move up, so as to provide sealing between the splash shield and the splash shield base.

In a third aspect, an embodiment of the present application provides an electronic device comprising a memory, a processor, and a computer program stored on the memory and executable on the processor, wherein when the processor executes the computer program, the sealing method described in the second aspect above is implemented.

In a fourth aspect, an embodiment of the present application provides a storage medium, with a computer program stored on the storage medium, wherein when the program is executed by a processor, the sealing method described in the second aspect above is implemented.

Compared with the related art, the embodiment of the present application provides a sealing method, an electronic device, a storage medium, and a semiconductor processing apparatus. The semiconductor processing apparatus comprises a lift module, a detection module, and a control module, and the control module is coupled between the lift module and the detection module, wherein the lift module is configured to drive the splash shield to move up and down; the detection module is configured to detect a gas-flow parameter between the splash shield and the splash shield base; the control module is configured to control the lift module to drive the splash shield to move up and down according to the gas-flow parameter, so as to provide sealing between the splash shield and the splash shield base. By the above means, the problem in the related art that the wafer yield is reduced due to the poor sealing performance between the splash shield and the splash shield base is solved, the sealing performance between the splash shield and the splash shield base is improved, and the wafer yield is also improved accordingly.

The details of one or more embodiments of the present application are set forth in the following accompanying drawings and description to make other features, objects, and advantages of the present application more concise and easier to understand.

### BRIEF DESCRIPTION OF THE DRAWINGS

The accompanying drawings described herein are used to provide a further understanding of the present application and constitute a part of the present application. The schematic embodiments of the present application and the description of the embodiments are used to illustrate the present application and do not constitute any improper limitation on the present application. In the accompanying drawings:

FIG. 1 is a schematic structure diagram of a semiconductor processing apparatus according to the related art;

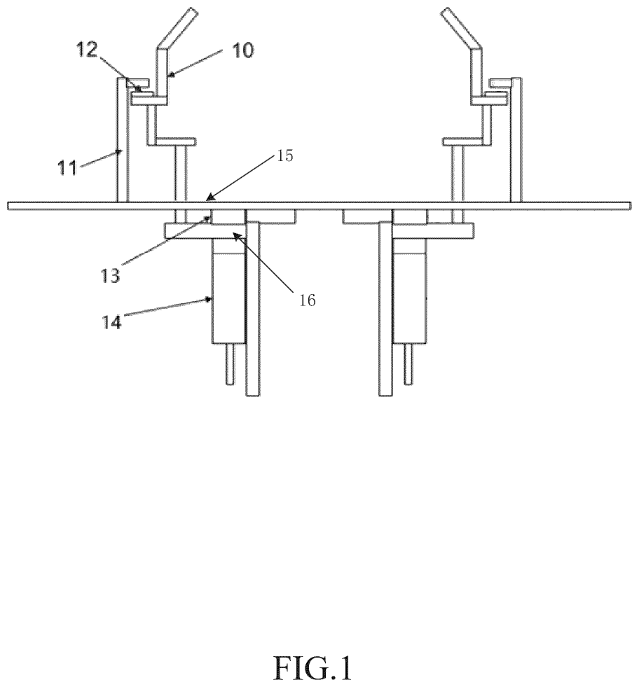

FIG. 2 is a schematic structure diagram of a semiconductor processing apparatus according to an embodiment of the present application; and

FIG. 3 is a flowchart of a sealing method according to an embodiment of the present application.

### DETAILED EMBODIMENTS OF THE INVENTION

In order to make the objects, technical solutions, and advantages of the present application clearer and easier to understand, the present application will be described and illustrated below with reference to the accompanying drawings and embodiments. It should be understood that the specific embodiments described herein are only used to illustrate the present application and are not used to limit the present application. Based on the embodiments provided in the present application, all other embodiments obtained by those of ordinary skill in the art without making creative efforts shall fall within the protection scope of the present application. In addition, it can be understood that although the efforts made in this development process may be complex and time-consuming, for those of ordinary skill in the art related to the content disclosed in the present application, some design, manufacturing, or production changes made on the basis of the technical content disclosed in the present application are only conventional technical means and should not be taken to mean that the present application is insufficiently disclosed.

The reference to “the embodiment” in the present application means that the specific features, structures, or characteristics described with reference to the embodiment can be included in at least one embodiment of the present application. The appearance of this phrase at different locations in the specification does not necessarily refer to the same embodiment, nor is it an independent or alternative embodiment that is mutually exclusive with other embodiments. Those of ordinary skill in the art clearly and implicitly understand that the embodiment described in the present application can, in the absence of conflict, be combined with other embodiments.

Unless otherwise defined, the technical terms or scientific terms involved in the present application shall have the usual meanings understood by those of ordinary skill in the art to which the present application belongs. The terms such as “a/an,” “one,” and “the” involved in the present application do not indicate a limitation on quantity and can indicate a singular or plural number. The terms “include,” “comprise,” “have,” and the variations of “include,” “comprise,” and “have” involved in the present application are intended to cover non-exclusive inclusions; for example, a process, method, system, product, or device that includes a series of steps or modules (units) is not limited to the listed steps or units, but can further include unlisted steps or units, or can further include other steps or units inherent to the process, method, product, or device. The terms such as “connect,” “interconnect,” and “couple” involved in the present application are not limited to physical or mechanical connections, but can include electrical connections, whether direct or indirect. The term “a plurality of” involved in the present application means two or more. The term “and/or” involved in the present application describes the associative relationship of the associated objects, indicating that three relationships may exist. For example, “A and/or B” can indicate: A alone, A and B together, and B alone. The terms such as “first,” “second,” and “third” involved in the present application are only used to distinguish similar objects and do not represent a specific order of the objects.

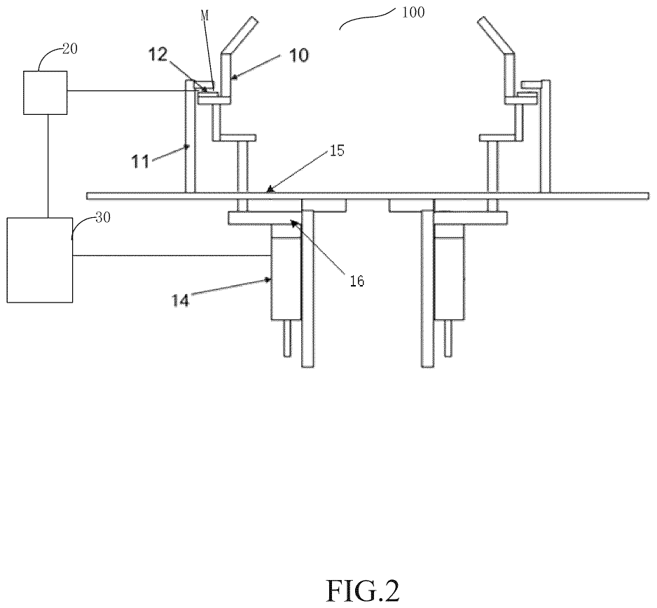

The present embodiment provides a semiconductor processing apparatus 100. FIG. 2 is a schematic structure diagram of the semiconductor processing apparatus according to the embodiment of the present application. As shown in FIG. 2, the apparatus comprises a splash shield 10, a splash shield base 11, a lift module 14, a detection module 20, and a control module 30. The control module 30 is coupled between the lift module 14 and the detection module 20, wherein, the lift module 14 is configured to drive the splash shield 10 to move up and down; the detection module 20 is configured to detect the gas-flow parameter between the splash shield 10 and the splash shield base 11; the control module 30 is configured to control the lift module 14 to drive the splash shield 10 to move up and down according to the gas-flow parameter, so as to provide sealing between the splash shield 10 and the splash shield base 11.

In the present embodiment, a detection module 20 is arranged between the splash shield 10 and the splash shield base 11 to detect the gas-flow parameter between the splash shield 10 and the splash shield base 11; then the control module 30 controls the lift module 14 to drive the splash shield 10 to move up and down according to the gas-flow parameter, so as to provide sealing between the splash shield 10 and the splash shield base 11. This avoids the problem in the related art that the lifting height of the splash shield 10 is structurally fixed due to the use of a hard stop 13, precluding the automatic adjustment between the splash shield 10 and the splash shield base 11, which leads to poor sealing performance between the splash shield 10 and the splash shield base 11 and affects the wafer yield. By means of providing adjustable lifting of the splash shield 10 based on the gas-flow parameter, the present application improves the sealing performance between the splash shield 10 and the splash shield base 11 and also increases the wafer yield.

It should be noted that the gas-flow parameter may include, for example, one or more of the following: gas-flow velocity and spacing, and can also be other parameters that can affect the gas flow between the splash shield 10 and the splash shield base 11. No particular restriction is imposed on the parameter in the present application.

The lift module 14 in the present embodiment may be a linear lifting cylinder, a lifting motor, or the like that can provide the lifting function, or may be other structures that can implement the solution of the present application and provide the lifting function.

In some embodiments, the detection module 20 comprises a velocity sensing unit. The velocity sensing unit is coupled with the control module 30 and is configured to detect the gas-flow velocity between the splash shield 10 and the splash shield base 11. In the present embodiment, the velocity sensing unit is configured to detect the gas-flow velocity between the splash shield 10 and the splash shield base 11, so that the gas-flow velocity can be accurately obtained. The control module 30 controls the lifting unit to drive the splash shield 10 to move up and down according to the gas-flow velocity, thereby providing sealing between the splash shield 10 and the splash shield base 11.

It should be noted that the velocity sensing unit may be some devices or sensors that can detect gas-flow velocity or gas flow.

In some embodiments, the control module 30 comprises a first determination unit and a first control unit. The first determination unit is coupled with the velocity sensing unit, and the first control unit is coupled between the first determination unit and the lift module 14, wherein, the first determination unit is configured to determine whether the gas-flow velocity detected by the velocity sensing unit is greater than a preset gas-flow velocity; the first control unit is configured to control the lift module 14 to drive the splash shield 10 to move up when the first determination unit determines that the gas-flow velocity detected by the velocity sensing unit is greater than the preset gas-flow velocity, and to control the lift module 14 to halt the upward movement when the gas-flow velocity detected by the velocity sensing unit is smaller than the preset gas-flow velocity, so as to provide tightly controlled sealing between the splash shield 10 and the splash shield base 11.

In the present embodiment, the splash shield 10 is automatically adjusted by comparing the actual gas-flow velocity between the splash shield 10 and the splash shield base 11 with a preset gas-flow velocity. This solves the problem in the related art that a hard stop 13 is used, precluding the automatic adjustment between the splash shield 10 and the splash shield base 11, which leads to poor sealing performance between the splash shield 10 and the splash shield base 11 and reduces the wafer yield. The sealing performance between the splash shield 10 and the splash shield base 11 is further improved, and the wafer yield is also improved.

It should be noted that the preset gas-flow velocity can be set to different values according to different wafer processes, and no particular restriction is imposed on the values in the present application.

In some embodiments, the detection module 20 comprises a distance measuring unit. The distance measuring unit is coupled with the control module 30 and is configured to measure the spacing between the splash shield 10 and the splash shield base 11.

In the present embodiment, the distance measuring unit is configured to measure the spacing between the splash shield 10 and the splash shield base 11, and the specific position of the spacing is at position M in FIG. 2, so that the spacing between the splash shield 10 and the splash shield base 11 can be accurately obtained. The control module 30 controls the lifting unit to drive the splash shield 10 to move up and down according to the spacing, thereby providing tightly controlled sealing between the splash shield 10 and the splash shield base 11.

It should be noted that the distance measuring unit may be some devices or sensors that can measure the spacing between the splash shield 10 and the splash shield base 11.

In the present embodiment, a seal ring 12 can also be arranged at position M in FIG. 2 to further enhance the sealing effect.

In some embodiments, the control module 30 comprises a second determination unit and a second control unit. The second determination unit is coupled with the distance measuring unit, and the second control unit is coupled between the second determination unit and the lift module 14, wherein, the second determination unit is configured to determine whether the spacing is greater than a preset spacing; the second control unit is configured to control the lift module 14 to drive the splash shield 10 to move up when the second determination unit determines that the spacing is greater than the preset spacing, and to control the lift module 14 to halt the upward movement when the spacing is smaller than the preset spacing, so as to provide sealing between the splash shield 10 and the splash shield base 11.

In the present embodiment, the splash shield 10 is automatically adjusted by comparing the spacing detected by the distance measuring unit with a preset spacing. This solves the problem in the related art that no automatic adjustment between the splash shield 10 and the splash shield base 11 could be achieved, which leads to poor sealing performance between the splash shield 10 and the splash shield base 11 and reduces the wafer yield. The sealing performance between the splash shield 10 and the splash shield base 11 is further improved.

It should be noted that the preset spacing can be set to different values according to different wafer processes, and no particular restriction is imposed on the values in the present application.

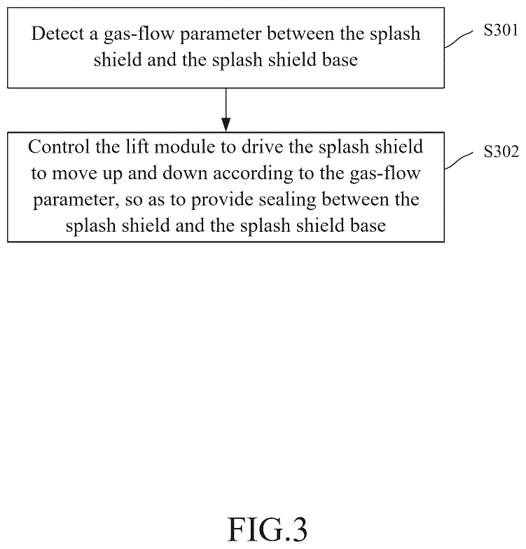

The embodiment of the present application further provides a sealing method applied to the semiconductor processing apparatus in the embodiments described above. FIG. 3 is a flowchart of the sealing method according to the embodiment of the present application. As shown in FIG. 3, the sealing method includes:

step S301: Detect the gas-flow parameter between the splash shield 10 and the splash shield base 11.

step S302: Control the lift module 14 to drive the splash shield 10 to move up and down according to the gas-flow parameter so as to provide sealing between the splash shield 10 and the splash shield base 11.

It should be noted that, when the spacing between the splash shield 10 and the splash shield base 11 is large, the sealing performance between the splash shield 10 and the splash shield base 11 becomes poor, and gas leakage occurs between the splash shield 10 and the splash shield base 11. Consequently, during a wafer process, part of the exhaust flow will escape through the gap, leading to a low process exhaust flow rate. This makes the acid vapor on the wafer surface fail to be promptly discharged, and the acid vapor adheres to the edge of the wafer and forms edge particle defects, affecting the wafer yield.

Therefore, in order to solve the above problems, the gas-flow parameter between the splash shield 10 and the splash shield base 11 is detected in the present embodiment, and then the lift module 14 is controlled to drive the splash shield 10 to move up and down according to the gas-flow parameter, so as to provide sealing between the splash shield 10 and the splash shield base 11. This avoids the problem in the related art that a hard stop 13 is used to structurally fix the lifting height of the splash shield 10, precluding the automatic adjustment between the splash shield 10 and the splash shield base 11, which leads to poor sealing performance between the splash shield 10 and the splash shield base 11, and affects the wafer yield. By means of providing adjustable lifting of the splash shield 10 based on the gas-flow parameter, the present application improves the sealing performance between the splash shield 10 and the splash shield base 11 and consequently increases the wafer yield.

In some embodiments, detecting the gas-flow parameter between the splash shield 10 and the splash shield base 11 includes: detecting the gas-flow velocity between the splash shield 10 and the splash shield base 11.

In the present embodiment, the gas-flow velocity between the splash shield 10 and the splash shield base 11 can be detected by the velocity sensing unit in the embodiments described above, so that the gas-flow velocity can be obtained accurately, and the control module 30 then controls the lifting unit to drive the splash shield 10 to move up and down according to the gas-flow velocity, thereby providing sealing between the splash shield 10 and the splash shield base 11.

In some embodiments, after the gas-flow velocity between the splash shield 10 and the splash shield base 11 is detected, whether the gas-flow velocity is greater than a preset gas-flow velocity can be further determined. When it is determined that the gas-flow velocity is greater than the preset gas-flow velocity, the lift module 14 is controlled to drive the splash shield 10 to move up, and the upward movement is halted when the gas-flow velocity is smaller than the preset gas-flow velocity, so as to provide tightly controlled sealing between the splash shield 10 and the splash shield base 11.

In the present embodiment, by comparing the gas-flow velocity with a preset gas-flow velocity, the splash shield 10 can be automatically adjusted, which solves the problem in the related art that no automatic adjustment between the splash shield 10 and the splash shield base 11 could be achieved, which leads to poor sealing performance between the splash shield 10 and the splash shield base 11 and reduces the wafer yield, and therefore improves the sealing performance between the splash shield 10 and the splash shield base 11 and also increases the wafer yield.

It should be noted that the preset gas-flow velocity can be set to different values according to different wafer processes, and no particular restriction is imposed on the values in the present application.

In some embodiments, detecting the gas-flow parameter between the splash shield 10 and the splash shield base 11 includes: detecting the spacing between the splash shield 10 and the splash shield base 11.

In the present embodiment, the spacing between the splash shield 10 and the splash shield base 11 can be measured by the distance measuring unit in the embodiments described above, so that the spacing can be obtained accurately, and the control module 30 then controls the lifting unit to drive the splash shield 10 to move up and down according to the spacing, thereby providing tightly controlled sealing between the splash shield 10 and the splash shield base 11.

In some embodiments, after the spacing between the splash shield 10 and the splash shield base 11 is measured, whether the spacing is greater than a preset spacing can be further determined. When it is determined that the spacing is greater than the preset spacing, the lift module 14 is controlled to drive the splash shield 10 to move up, and the upward movement is halted when the spacing is smaller than the preset spacing, so as to provide sealing between the splash shield 10 and the splash shield base 11.

In the present embodiment, by comparing the spacing with a preset spacing, the splash shield 10 can be automatically adjusted, which solves the problem in the related art that no automatic adjustment between the splash shield 10 and the splash shield base 11 could be achieved, which leads to poor sealing performance between the splash shield 10 and the splash shield base 11 and reduces the wafer yield. Therefore, the sealing performance between the splash shield 10 and the splash shield base 11 is further improved.

It should be noted that the preset spacing can be set to different values according to different wafer processes, and no particular restriction is imposed on the values in the present application.

The present embodiment further provides an electronic device comprising a memory and a processor. A computer program is stored in the memory, and the processor is configured to run the computer program to execute the steps in any of the method embodiments described above.

Optionally, the electronic device described above may further comprise a transfer device and an input/output device, wherein the transfer device is connected to the processor described above, and the input/output device is connected to the processor described above.

Optionally, in the present embodiment, the processor described above can be configured to execute the following steps by running the computer program:

S1: Detect the gas-flow parameter between the splash shield and the splash shield base.

S2: Control the lift module to drive the splash shield to move up and down according to the gas-flow parameter, so as to provide sealing between the splash shield and the splash shield base.

It should be noted that specific examples in the present embodiment can be found by referring to the examples in the embodiments and optional embodiments described above, and the present embodiment will not repeat the examples here.

In addition, in combination with the sealing method in the embodiments described above, the embodiment of the present application can provide a storage medium for implementing the method. A computer program is stored on the storage medium. When the computer program is executed by a processor, any one of the sealing methods in the embodiments described above will be implemented.

Those skilled in the art should understand that various technical features of the embodiments described above can be combined in any combination. To make the description concise, not all possible combinations of the various technical features in the embodiments described above have been described. However, provided that the combinations of these technical features entail no technical inconsistency, any such combinations shall be regarded as falling within the scope of the present specification.

The embodiments described above merely illustrate several implementation methods of the present application and are described in a relatively specific and detailed manner; however, the embodiments shall not be construed as limiting the scope of the present patent application. It should be noted that for those of ordinary skill in the art, without departing from the concepts of the present application, a plurality of modifications and improvements can be made, and the modifications and improvements all fall within the protection scope of the present application. Therefore, the protection scope of the present patent application shall be defined by the appended claims.

1. A semiconductor processing apparatus, comprising:
a splash shield;
a splash shield base;
a lift module, configured to drive the splash shield to lift;
a detection module, configured to detect a gas-flow parameter between the splash shield and the splash shield base; and
a control module, coupled between the lift module and the detection module and configured to control the lift module to drive the splash shield to move up and down according to the gas-flow parameter, so as to provide sealing between the splash shield and the splash shield base.

2. The semiconductor processing apparatus according to claim 1, wherein the gas-flow parameter comprises gas-flow velocity, the detection module comprises a velocity sensing unit, and the velocity sensing unit is coupled with the control module and is configured to detect the gas-flow velocity between the splash shield and the splash shield base.

3. The semiconductor processing apparatus according to claim 2, wherein the control module comprises a first determination unit and a first control unit, the first determination unit is coupled with the velocity sensing unit, and the first control unit is coupled between the first determination unit and the lift module, wherein,
the first determination unit is configured to determine whether the gas-flow velocity is greater than a preset gas-flow velocity;
the first control unit is configured to control the lift module to drive the splash shield to move up when the first determination unit determines that the gas-flow velocity is greater than the preset gas-flow velocity, and to control the lift module to halt the upward movement when the gas-flow velocity is smaller than the preset gas-flow velocity, so as to provide sealing between the splash shield and the splash shield base.

4. The semiconductor processing apparatus according to claim 1, wherein the gas-flow parameter comprises spacing;
the detection module comprises a distance measuring unit, and the distance measuring unit is coupled with the control module and is configured to measure the spacing between the splash shield and the splash shield base.

5. The semiconductor processing apparatus according to claim 4, wherein the control module comprises a second determination unit and a second control unit, the second determination unit is coupled with the distance measuring unit, and the second control unit is coupled between the second determination unit and the lift module, wherein,
the second determination unit is configured to determine whether the spacing is greater than a preset spacing;
the second control unit is configured to control the lift module to drive the splash shield to move up when the second determination unit determines that the spacing is greater than the preset spacing, and to control the lift module to halt the upward movement when the spacing is smaller than the preset spacing, so as to provide sealing between the splash shield and the splash shield base.

6. A sealing method, applied to a semiconductor processing apparatus comprising a splash shield, a splash shield base, and a lift module, including:
detecting a gas-flow parameter between the splash shield and the splash shield base;
controlling the lift module to drive the splash shield to move up and down according to the gas-flow parameter, so as to provide sealing between the splash shield and the splash shield base.

7. The sealing method according to claim 6, wherein the gas-flow parameter comprises gas-flow velocity;
detecting the gas-flow parameter between the splash shield and the splash shield base includes: detecting the gas-flow velocity between the splash shield and the splash shield base.

8. The sealing method according to claim 7, wherein after detecting the gas-flow velocity between the splash shield and the splash shield base, the method further includes:
determining whether the gas-flow velocity is greater than a preset gas-flow velocity;
controlling the lift module to drive the splash shield to move up when it is determined that the gas-flow velocity is greater than the preset gas-flow velocity, so as to provide sealing between the splash shield and the splash shield base.

9. The sealing method according to claim 6, wherein the gas-flow parameter comprises spacing;
detecting the gas-flow parameter between the splash shield and the splash shield base includes: detecting the spacing between the splash shield and the splash shield base.

10. The sealing method according to claim 9, wherein after detecting the spacing between the splash shield and the splash shield base, the method further includes:
determining whether the spacing is greater than a preset spacing;
controlling the lift module to drive the splash shield to move up when it is determined that the spacing is greater than the preset spacing, so as to provide sealing between the splash shield and the splash shield base.

11. An electronic device, comprising a memory and a processor, wherein a computer program is stored in the memory, and the processor is configured to run the computer program to execute the sealing method according to claim 6.

12. (canceled)
